(19) United States
(12) Patent Application Publication
(10) Pub. No.: US 2025/0176228 A1
(43) Pub. Date: May 29, 2025

(54) SEMICONDUCTOR DEVICE AND METHOD OF FABRICATING THE SAME

(71) Applicant: SAMSUNG ELECTRONICS CO., LTD., SUWON-SI (KR)

(72) Inventors: Jong Woon YOON, Suwon-si (KR); Yong Hee PARK, Suwon-si (KR); Jae-Hyun YOO, Suwon-si (KR); Jun Hyeok KIM, Suwon-si (KR); Joo Won PARK, Suwon-si (KR)

(21) Appl. No.: 18/824,162

(22) Filed: Sep. 4, 2024

(30) Foreign Application Priority Data
Nov. 24, 2023 (KR) 10-2023-0165841

(51) Int. Cl. H01L 29/06; H01L 29/66; H01L 29/861

(52) U.S. Cl. CPC H10D 62/102; H10D 8/00; H10D 62/124; H10D 8/01

(57) ABSTRACT

A semiconductor device includes a substrate that includes a first region and a second region that surrounds the first region, an epitaxial layer disposed in the first and second regions, where the epitaxial layer has a first conductivity type, a buried layer disposed below the epitaxial layer, where the buried layer has a second conductivity type that differs from the first conductivity type, a first high-concentration impurity region within the epitaxial layer in the first region, where the first high-concentration impurity region overlaps a top surface of the epitaxial layer and has the first conductivity type, a second high-concentration impurity region within the epitaxial layer in the first region, where the second high-concentration impurity region overlaps the top surface of the epitaxial layer and has the second conductivity type, and a device isolation film disposed on the epitaxial layer between the first and second high-concentration impurity regions.

### CROSS-REFERENCE TO RELATED APPLICATION

This application claims priority under 35 U.S.C. 119 from Korean Patent Application No. 10-2023-0165841, filed on Nov. 24, 2023 in the Korean Intellectual Property Office, the contents of which are herein incorporated by reference in their entirety.

### TECHNICAL FIELD

Embodiments of the present disclosure are directed to a semiconductor device and a method of fabricating the same, and more particularly, to a semiconductor device that includes high-voltage power diodes and a method of fabricating the semiconductor device.

### DISCUSSION OF THE RELATED ART

Power diodes are power components for high voltage applications that are widely used in direct current (DC)/alternating current (AC) converters. These high-voltage power diodes can require high breakdown voltage and low on-resistance.

High-voltage power diodes can be manufactured alongside various other components through a bipolar-complementary metal-oxide semiconductor (CMOS)-double-diffused metal-oxide semiconductor (DMOS) (BCD) process. A BCD process involves implementing bipolar transistors, CMOS transistors, and DMOS transistors on a single semiconductor substrate and can be utilized in the production of various power components.

### SUMMARY

Embodiments of the present disclosure provide a semiconductor device with an improved breakdown voltage.

Embodiments of the present disclosure also provide a method of fabricating a semiconductor device with an improved breakdown voltage.

According to an embodiment of the present disclosure, there is provided a semiconductor device that includes a substrate that includes a first region and a second region that surrounds the first region, an epitaxial layer disposed in the first and second regions, where the epitaxial layer has a first conductivity type, a buried layer disposed below the epitaxial layer, where the buried layer has a second conductivity type that differs from the first conductivity type, a first high-concentration impurity region within the epitaxial layer in the first region, where the first high-concentration impurity region overlaps a top surface of the epitaxial layer and has the first conductivity type, a second high-concentration impurity region within the epitaxial layer in the first region, where the second high-concentration impurity region overlaps the top surface of the epitaxial layer and has the second conductivity type, a device isolation film disposed on the epitaxial layer between the first and second high-concentration impurity regions, where the device isolation film is disposed adjacent to the second high-concentration impurity region, a drift region within the epitaxial layer below the device isolation film and second high-concentration impurity region, where the drift region has the second conductivity type, a high-voltage well within the epitaxial layer below the drift region, where the high-voltage well has the second conductivity type, a third high-concentration impurity region within the epitaxial layer in the second region, where the third high-concentration impurity region overlaps the top surface of the epitaxial layer and has the second conductivity type, and an isolation well within the epitaxial layer in the second region, wherein the isolation well connects the buried layer and the third high-concentration impurity region and has the second conductivity type. An impurity concentration of the high-voltage well is lower than an impurity concentration of the isolation well.

According to an embodiment of the present disclosure, there is provided a semiconductor device that includes a substrate, an epitaxial layer disposed on the substrate, where the epitaxial layer has a first conductivity type, a buried layer disposed below the epitaxial layer, where the buried layer has a second conductivity type that differs from the first conductivity type, a first high-concentration impurity region within the epitaxial layer, where the first high-concentration impurity region overlaps a top surface of the epitaxial layer and has the first conductivity type, a second high-concentration impurity region within the epitaxial layer, where the second high-concentration impurity region overlaps the top surface of the epitaxial layer and has the second conductivity type, a device isolation film disposed on the epitaxial layer between the first and second high-concentration impurity regions, where the device isolation film is adjacent to the second high-concentration impurity region, a drift region within the epitaxial layer below the device isolation film and second high-concentration impurity region, where the drift region has the second conductivity type, and a high-voltage well within the epitaxial layer below the drift region, where the high-voltage well has the second conductivity type. The buried layer includes a base portion below the first high-concentration impurity region, and an extension portion that extends from the base portion and is located below the high-voltage well, and an impurity concentration of the extension portion is lower than an impurity concentration of the base portion.

According to an embodiment of the present disclosure, there is provided a semiconductor device that includes a substrate that includes a first region and a second region that surrounds the first region, a P-type epitaxial layer disposed in the first and second regions, an N-type buried layer disposed below the P-type epitaxial layer, a P-type high-concentration impurity region within the P-type epitaxial layer in the first region, where the P-type high-concentration impurity region overlaps a top surface of the P-type epitaxial layer, a first N-type high-concentration impurity region within the P-type epitaxial layer in the first region, where the first N-type high-concentration impurity region overlaps the top surface of the P-type epitaxial layer, a device isolation film disposed on the P-type epitaxial layer between the P-type high-concentration impurity region and the first N-type high-concentration impurity region, where the device isolation film is adjacent to the first N-type high-concentration impurity region, a gate electrode disposed on the P-type epitaxial layer between the P-type high-concentration impurity region and the first N-type high-concentration impurity region, where the gate electrode is adjacent to the P-type high-concentration impurity region, an N-type drift region within the P-type epitaxial layer below the device isolation film and first N-type high-concentration impurity region, an N-type high-voltage well within the P-type epitaxial layer below the N-type drift region, a second N-type high-concentration impurity region within the P-type epitaxial layer in the second region, where the second N-type high-concentration impurity region is between the top surfaces of the P-type epitaxial layer, and an N-type isolation well disposed within the P-type epitaxial layer on the second region, where the N-type isolation well connects the N-type buried layer and the second N-type high-concentration impurity region. An impurity concentration of the N-type high-voltage well is lower than an impurity concentration of the N-type isolation well. The N-type buried layer includes a base portion below the P-type high-concentration impurity region, and an extension portion that extends from the base portion and is located below the high-voltage well, and an impurity concentration of the extension portion is lower than an impurity concentration of the base portion.

### BRIEF DESCRIPTION OF THE DRAWINGS

FIG. 1 illustrates a layout of a semiconductor device according to some embodiments of the present disclosure.

FIG. 2 illustrates first and second regions of FIG. 1.

FIG. 3 is a cross-sectional view taken along lines A-A and B-B of FIG. 2.

FIG. 4 is a graph of the breakdown voltage of a semiconductor device according to some embodiments of the present disclosure.

FIG. 5 is cross-sectional view of a semiconductor device according to some embodiments of the present disclosure.

FIG. 6 is a cross-sectional view of a semiconductor device according to some embodiments of the present disclosure.

FIG. 7 illustrates a layout of a semiconductor device according to some embodiments of the present disclosure.

FIG. 8 illustrates a layout of a semiconductor device according to some embodiments of the present disclosure.

FIG. 9 is a graph of the breakdown voltage of a semiconductor device according to some embodiments of the present disclosure.

FIGS. 10 through 18 are cross-sectional views that illustrate intermediate stages of a method of fabricating a semiconductor device according to some embodiments of the present disclosure.

FIGS. 19 and 20 are cross-sectional views that illustrate a method of fabricating a semiconductor device according to some embodiments of the present disclosure.

### DETAILED DESCRIPTION

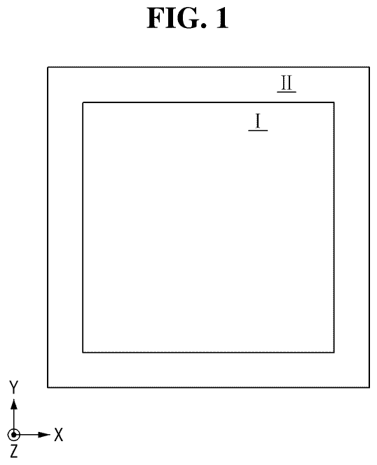

Semiconductor devices according to some embodiments of the present disclosure will hereinafter be described with reference to FIGS. 1 through 9.

In some embodiments, a semiconductor device is fabricated alongside various other components through a bipolar-complementary metal-oxide semiconductor-double-diffused metal-oxide semiconductor (BCD) process. For example, components fabricated together on a single semiconductor substrate through the BCD process include, but are not limited to, nLDMOS, pLDMOS, isolated CMOS, BiCMOS, CDMOS, nDMOS, pDMOS, vertical NPN, lateral PNP, Schottky diode, etc.

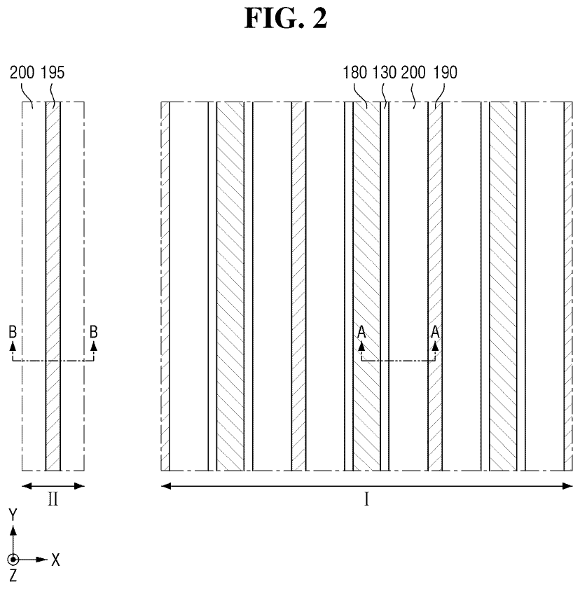

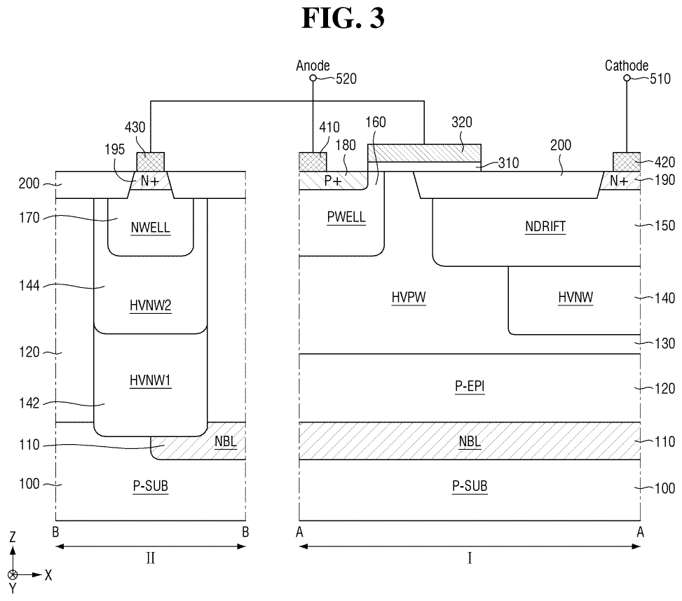

FIG. 1 illustrates a layout of a semiconductor device according to some embodiments of the present disclosure. FIG. 2 illustrates first and second regions of FIG. 1. FIG. 3 is a cross-sectional view taken along lines A-A and B-B of FIG. 2.

Referring to FIGS. 1 through 3, in some embodiments, a semiconductor device includes a substrate 100, a buried layer 110, an epitaxial layer 120, first high-voltage wells 130, second high-voltage wells 140, isolation wells 142 and 144, drift regions 150, first well regions 160, a second well region 170, first high-concentration impurity regions 180, second high-concentration impurity regions 190, a third high-concentration impurity region 195, a device isolation film 200, gate dielectric films 310, gate electrodes 320, first electrodes 410, second electrodes 420, and third electrodes 430.

The substrate 100 is a semiconductor substrate, such as a bulk silicon substrate, a silicon-on-insulator (SOI) substrate, a silicon (Si) substrate, or may include other materials such as silicon-germanium (SiGe), silicon germanium-on-insulator (SGOI), indium antimonide, a lead telluride compound, indium phosphide, gallium antimonide, or gallium arsenide. In some embodiments, the substrate 100 includes an epitaxial layer formed on a base substrate. For convenience, the substrate 100 will hereinafter be described as being a Si substrate.

The substrate 100 includes a first region I and a second region II. The first region I is where power components, such as high-voltage power diodes, are formed and includes the drift regions 150, the first high-concentration impurity regions 180, and the second high-concentration impurity regions 190. The first region I is illustrated as having a rectangular shape in a plan view, but embodiments of the present disclosure are not necessarily limited thereto. For example, the first region I may have various other shapes. The second region II surrounds the first region I. For example, the second region II surrounds the first region I in a plane, such as an XY plane that is defined by first and second directions X and Y. The second region II is an isolation region that electrically isolates the first region I from other areas of the substrate 100.

In some embodiments, the substrate 100 has a first conductivity type. For convenience, the first conductivity type will hereinafter be described as being a P type. For example, the substrate 100 is a P-type substrate (“P-SUB”) that contains P-type impurities such as boron (B), indium (In), gallium (Ga), or aluminum (Al).

The buried layer 110 is formed on the substrate 100. The buried layer 110 has a second conductivity type that differs from the first conductivity type. For example, the buried layer 110 is formed by doping N-type impurities, such as phosphorus (P), antimony (Sb), or arsenic (As), into an upper part of the substrate 100. For example, the buried layer 110 is an N-type buried layer (“NBL”). The buried layer 110 is a high-concentration impurity region that is doped with a relatively high concentration of impurities. For example, the concentration of N-type impurities, such as phosphorus (P), doped into the buried layer 110 may be approximately 10E19 cm⁻³ to approximately 10E20 cm⁻³.

The buried layer 110 is formed across the first and second regions I and II. In some embodiments, the buried layer 110 is formed on the entire first region I, and on part of the second region II.

The epitaxial layer 120 is formed on the substrate 100 and/or the buried layer 110. The epitaxial layer 120 is formed across the first and second regions I and II. The epitaxial layer 120 is grown from the substrate 100 and/or the buried layer 110 by an epitaxial growth method. The epitaxial layer 120 has the first conductivity type. For example, the epitaxial layer 120 is a P-type epitaxial layer (“P-EPI”) that contains P-type impurities, such as B, In, Ga, or Al.

The first high-voltage wells 130 is formed within the epitaxial layer 120 on the first region I. Top surfaces of the first high-voltage wells 130 are coplanar with a top surface of the epitaxial layer 120. The first high-voltage wells 130 have the first conductivity type. For example, the first high-voltage wells 130 are formed by doping P-type impurities, such as, B, In, Ga, or Al, into an upper part of the epitaxial layer 120. For example, the first high-voltage wells 130 is high-voltage P-type wells (“HVPW”).

In some embodiments, the first high-voltage wells 130 are not formed within the epitaxial layer 120 in the second region II. In some embodiments, the first high-voltage wells 130 are omitted.

The drift regions 150 are formed within the epitaxial layer 120 on the first region I. The drift regions 150 have the second conductivity type. For example, the drift regions 150 are formed by doping N-type impurities, such as P, Sb, or As, into parts of the first high-voltage wells 130. For example, the drift regions 150 are N-type drift regions (“NDRIFT”). The drift regions 150 are low-concentration impurity regions that are doped with a relatively low concentration of impurities. For example, the concentration of N-type impurities, such as P, doped into the drift regions 150 is approximately 10E16 cm−3 to approximately 10E18 cm−3.

The first well regions 160 are formed within the epitaxial layer 120 on the first region I. Top surfaces of the first well regions 160 are coplanar with the top surface of the epitaxial layer 120. The first well regions 160 are spaced apart from the drift regions 150. For example, parts of the first high-voltage wells 130 are interposed between the drift regions 150 and the first well regions 160. The first well regions 160 have the first conductivity type. For example, the first well regions 160 are formed by doping P-type impurities, such as B, In, Ga, or Al, into upper parts of the first high-voltage wells 130. The first well regions 160 are P-type wells (“PWELL”). The concentration of P-type impurities, such as B, doped into the first well regions 160 is approximately 10E17 cm−3 to approximately 10E18 cm−3.

The second well region 170 are formed within the epitaxial layer 120 in the second region II. A top surface of the second well region 170 is coplanar with the top surface of the epitaxial layer 120. The second well region 170 has the second conductivity type. For example, the second well region 170 is formed by doping N-type impurities, such as P, Sb, or As, into upper parts of the isolation wells 142 and 144. The second well region 170 is an N-type well (“NWELL”). The concentration of N-type impurities, such as P, doped into the second well region 170 is approximately 10E17 cm−3 to approximately 10E18 cm−3.

In some embodiments, at least part of the second well region 170 overlaps the buried layer 110. Here, the expression “overlap” means that at least part of the second well region 170 is arranged to overlap the buried layer 110 in a third direction Z that intersects the top surface of the substrate 100, or intersects the first and second directions X and Y.

The first high-concentration impurity regions 180 are formed within the first well regions 160. Top surfaces of the first high-concentration impurity regions 180 are coplanar with the top surface of the epitaxial layer 120. The first high-concentration impurity regions 180 have the first conductivity type. For example, the first high-concentration impurity regions 180 are formed by doping P-type impurities, such as B, In, Ga, or Al, into upper parts of the first well regions 160. The first high-concentration impurity regions 180 are a P-type high-concentration impurity regions (“P+”). The impurity concentration of the first high-concentration impurity regions 180 is higher than the impurity concentration of the first well regions 160. For example, the concentration of P-type impurities (e.g., B) doped into the first high-concentration impurity regions 180 is approximately 10E19 cm−3 to approximately 10E20 cm−3.

The first electrodes 410 are formed on the first high-concentration impurity regions 180. The first electrodes 410 are electrically connected to the first high-concentration impurity regions 180. In some embodiments, the first electrodes 410 serve as anodes 520 (“Anode”) of high-voltage power diodes. For example, a ground voltage is applied to the first electrodes 410.

The second high-concentration impurity regions 190 are formed within the drift regions 150. Top surfaces of the second high-concentration impurity regions 190 are coplanar with the top surface of the epitaxial layer 120. The second high-concentration impurity regions 190 have the second conductivity type. For example, the second high-concentration impurity regions 190 are formed by doping N-type impurities, such as P, Sb, or As, into upper parts of the drift regions 150. The second high-concentration impurity regions 190 are N-type high-concentration impurity regions (“N+”). The impurity concentration of the second high-concentration impurity regions 190 is higher than the impurity concentration of the drift regions 150. For example, the concentration of N-type impurities, such as P, doped into the second high-concentration impurity regions 190 is approximately 10E19 cm−3 to approximately 10E20 cm−3.

The second electrodes 420 are formed on the second high-concentration impurity regions 190. The second electrodes 420 are electrically connected to the second high-concentration impurity regions 190. In some embodiments, the second electrodes 420 serve as cathodes 510 (“Cathode”) of the high-voltage power diodes.

In some embodiments, the first high-concentration impurity regions 180 and the second high-concentration impurity regions 190 extend in parallel in the second direction Y. For example, as illustrated in FIG. 2, the first high-concentration impurity regions 180 and the second high-concentration impurity regions 190 are arranged along the first direction X and extend longitudinally in the second direction Y.

The third high-concentration impurity region 195 is formed within the second well region 170. A top surface of the third high-concentration impurity region 195 is coplanar with the top surface of the epitaxial layer 120. The third high-concentration impurity region 195 has the second conductivity type. For example, the third high-concentration impurity region 195 is formed by doping N-type impurities, such as P, Sb, or As, into an upper part of the second well region 170. The third high-concentration impurity region 195 is an N-type high-concentration impurity region (“N+”). The impurity concentration of the third high-concentration impurity region 195 is higher than the impurity concentration of the second well region 170. For example, the concentration of N-type impurities, such as P, doped into the third high-concentration impurity region 195 is approximately 10E19 cm−3 to approximately 10E20 cm−3.

In some embodiments, the third high-concentration impurity region 195 is formed at the same level as the second high-concentration impurity regions 190. In this specification, the expression “formed at the same level” means that the third high-concentration impurity region 195 and the second high-concentration impurity regions 190 are created by the same manufacturing process. For example, the impurity concentration of the third high-concentration impurity region 195 is the same as the impurity concentration of the second high-concentration impurity regions 190.

The third electrodes 430 are formed on the third high-concentration impurity region 195. The third electrodes 430 is electrically connected to the third high-concentration impurity region 195. In some embodiments, the third electrodes 430 are connected to the first electrodes 410. For example, the same voltage can be applied to the first electrodes 410 and the third electrodes 430. For example, the ground voltage can be applied to the third electrodes 430.

The device isolation film 200 is formed on the epitaxial layer 120 on the first and second regions I and II. In some embodiments, a top surface of the device isolation film 200 is coplanar with the top surface of the epitaxial layer 120 in the second region II. The device isolation film 200 can be formed by a process such as shallow trench isolation (STI) or LOCal Oxidation of Silicon (LOCOS).

The device isolation film 200 in the first region I is interposed between the first high-concentration impurity regions 180 and the second high-concentration impurity regions 190. In addition, the device isolation film 200 in the first region I is formed over parts of the first high-voltage wells 130 and drift regions 150. In some embodiments, the device isolation film 200 in the first region I is formed across parts of both the first high-voltage wells 130 and the drift regions 150.

The first high-concentration impurity regions 180 are spaced apart from the device isolation film 200. The first high-concentration impurity regions 190 is spaced apart from the first well regions 160. For example, parts of the first well regions 160 are interposed between the device isolation film 200 and the first high-concentration impurity regions 180. In some embodiments, parts of the first high-voltage wells 130 are interposed between the device isolation film 200 and the first well regions 160.

The second high-concentration impurity regions 190 are adjacent to the device isolation film 200. For example, the second high-concentration impurity regions 190 are formed by doping N-type impurities, such as P, Sb, or As, into upper parts of the drift regions 150 exposed by the device isolation film 200. The drift regions 150 are formed below the device isolation film 200 and second high-concentration impurity regions 190.

The device isolation film 200 in the second region II is formed on both sides of the third high-concentration impurity region 195. For example, the third high-concentration impurity region 195 is formed by doping N-type impurities, such as P, Sb, or As, into the upper part of the second well region 170 exposed by the device isolation film 200. The second well regions 170 are formed below the device isolation film 200 and third high-concentration impurity regions 195.

The second high-voltage wells 140 are formed within the first high-voltage wells 130 in the first region I. The second high-voltage wells 140 are formed below the drift regions 150. The second high-voltage wells 140 are adjacent to the drift regions 150. The second high-voltage wells 140 are spaced apart from the buried layer 110. The second high-voltage wells 140 have the second conductivity type. For example, the second high-voltage wells 140 are formed by doping N-type impurities, such as P, Sb, or As, into other parts of the first high-voltage wells 130 that are placed below the drift regions 150. For example, the second high-voltage wells 140 are high voltage N-type wells (“HVNW”). In some embodiments, parts of the first high-voltage wells 130 are interposed between the buried layer 110 and the second high-voltage wells 140.

At least portions of the second high-voltage wells 140 overlap the second high-concentration impurity regions 190 in the third direction Z. In some embodiments, the second high-voltage wells 140 protrude toward the first high-concentration impurity regions 180, or the first well regions 160, beyond the second high-concentration impurity regions 190. For example, other portions of the second high-voltage wells 140 overlap the device isolation film 200 in the third direction Z. In some embodiments, the drift regions 150 protrude toward the first high-concentration impurity regions 180 or the first well regions 160 beyond the second high-voltage wells 140.

The isolation wells 142 and 144 are formed in the second region II. The isolation wells 142 and 144 are formed on the buried layer 110 and below the second well region 170. The isolation wells 142 and 144 connect the buried layer 110 and the second well region 170. The isolation wells 142 and 144 have the second conductivity type. For example, the isolation wells 142 and 144 are formed by doping N-type impurities, such as P, Sb, or As, into a portion of the epitaxial layer 120 on the buried layer 110 in the second region II. For example, the isolation wells 142 and 144 are high voltage N-type wells (“HVNW”).

The isolation wells 142 and 144 surround the first region I in a plan view. For example, the isolation wells 142 and 144 surround the first region I in the plane, such as the XY plane, that is defined by the first and second directions X and Y. The buried layer 110 and the isolation wells 142 and 144 electrically isolate the first region I from other regions of the substrate 100.

In some embodiments, the isolation wells 142 and 144 include first and second sub-isolation wells 142 and 144 that are sequentially formed on the buried layer 110. The first sub-isolation well 142 connects the buried layer 110 and the second sub-isolation well 144, and the second sub-isolation well 144 connects the first sub-isolation well 142 and the second well region 170. The first and second sub-isolation wells 142 and 144 have the second conductivity type. For example, the first sub-isolation well 142 is a high voltage N-type well (“HVNW”), and the second sub-isolation well 144 is a high voltage N-type well (“HVNW”) with a smaller projected range (Rₚ) than the first sub-isolation well 142. In some embodiments, the second high-voltage wells 140 is formed at the same level as the second sub-isolation well 144.

The second high-voltage wells 140 are low-doped impurity regions. The impurity concentration of the second high-voltage wells 140 is lower than the impurity concentration of the isolation wells 142 and 144. In some embodiments, the impurity concentration of the second high-voltage wells 140 is lower than the impurity concentration of the second sub-isolation well 144.

The gate dielectric films 310 and the gate electrodes 320 are formed on the epitaxial layer 120 on the first region I. The gate dielectric films 310 is interposed between the epitaxial layer 120 and the gate electrodes 320. The gate electrodes 320 are spaced apart from the epitaxial layer 120 by the gate dielectric films 310.

The gate electrodes 320 are formed on the first high-voltage wells 130between the first high-concentration impurity regions 180 and the second high-concentration impurity regions 190. In some embodiments, the gate electrodes 320 are formed across parts of the first high-voltage wells 130 and the device isolation film 200. For example, the gate electrodes 320 are formed across parts of the first well regions 160, first high-voltage wells 130, and device isolation film 200.

The first high-concentration impurity regions 180 are adjacent to the gate electrodes 320. For example, the first high-concentration impurity regions 180 are formed by doping P-type impurities, such as B, In, Ga, or Al, into the upper parts of the first well regions 160 exposed by the gate electrodes 320. Portions of the first well regions 160 between the device isolation film 200 and the first high-concentration impurity regions 180 are formed below the gate electrodes 320. In some embodiments, the portions of the first high-voltage wells 130 interposed between the device isolation film 200 and the first well regions 160 are formed below the gate electrodes 320.

The second high-concentration impurity regions 190 are spaced apart from the gate electrodes 320. For example, portions of the device isolation film 200 are formed below the gate electrodes 320, and other portions of the device isolation film 200 are interposed between the second high-concentration impurity regions 190 and the gate electrodes 320.

In some embodiments, the gate electrodes 320 are electrically connected to the first electrodes 410. For example, the same voltage can be applied to the first electrodes 410 and the gate electrodes 320. For example, the ground voltage can be applied to the gate electrodes 320.

The gate dielectric films 310 include, for example, at least one of silicon oxide, silicon nitride, silicon carbide, a dielectric material with a greater dielectric constant than silicon oxide, or a combination thereof, but embodiments of the present disclosure are not necessarily limited thereto. For example, the gate dielectric films 310 include silicon oxide films.

The gate electrodes 320 include a conductive material such as at least one of polysilicon (poly Si), amorphous silicon (a-Si), titanium (Ti), titanium nitride (TiN), tungsten nitride (WN), titanium aluminum (TiAl), titanium aluminum nitride (TiAlN), tantalum nitride (TaN), titanium carbide (TiC), tantalum carbide (TaC), tantalum carbon nitride (TaCN), tantalum silicon nitride (TaSiN), tantalum (Ta), cobalt (Co), ruthenium (Ru), Al, tungsten (W), or a combination thereof, but embodiments of the present disclosure are not necessarily limited thereto. For example, the gate electrodes 320 include polysilicon films.

As disclosed above, a semiconductor device according to some embodiments of the present disclosure includes the second high-voltage wells 140 formed below the drift regions 150. The second high-voltage wells 140 are, for example, high voltage N-type wells (“HVNW”) formed by a BCD process. The second high-voltage wells 140 enhance the REduced SURface Field (RESURF) effect by expanding depletion regions in a vertical direction, such as the third direction Z. Accordingly, high-voltage power diodes with an improved breakdown voltage can be provided.

Furthermore, since the second high-voltage wells 140 are located close to the buried layer 110, a punch-through phenomenon between the depletion regions caused by the second high-voltage wells 140 and the buried layer 110 may become problematic. However, as discloses above, since the second high-voltage wells 140 are relatively low-doped impurity regions as compared to the isolation wells 142 and 144, an excessive expansion of the depletion regions caused by the second high-voltage wells 140 can be prevented. Consequently, high-voltage power diodes with an improved breakdown voltage can be provided without the issue of leakage currents.

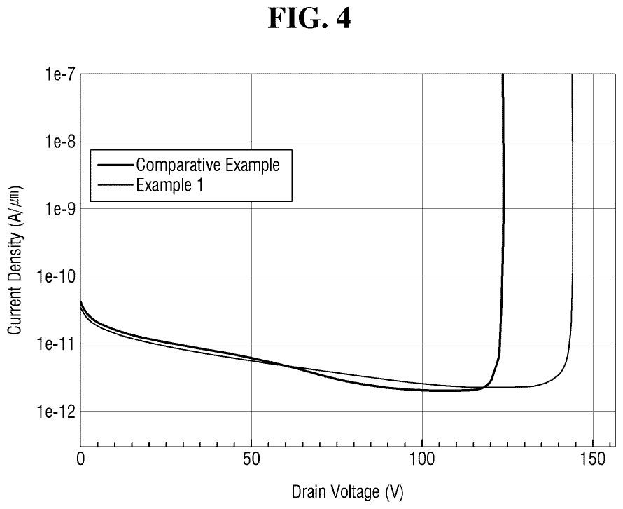

FIG. 4 is a graph of the breakdown voltage of a semiconductor device according to some embodiments of the present disclosure. For example, FIG. 4 is a graph that compares off-state current measurements from Example 1 and Comparative Example. Example 1 used an semiconductor device of FIGS. 1 to 3. Comparative Example used a similar semiconductor device that does not include the second high-voltage wells 140.

Referring to FIG. 4, a semiconductor device according to Example 1 has a significantly improved breakdown voltage of about 143 V, as compared to a semiconductor device according to Comparative Example, which has a breakdown voltage of about 123 V. This confirms that the breakdown voltage of high-voltage power diodes can be improved using the second high-voltage wells 140 of FIG. 3.

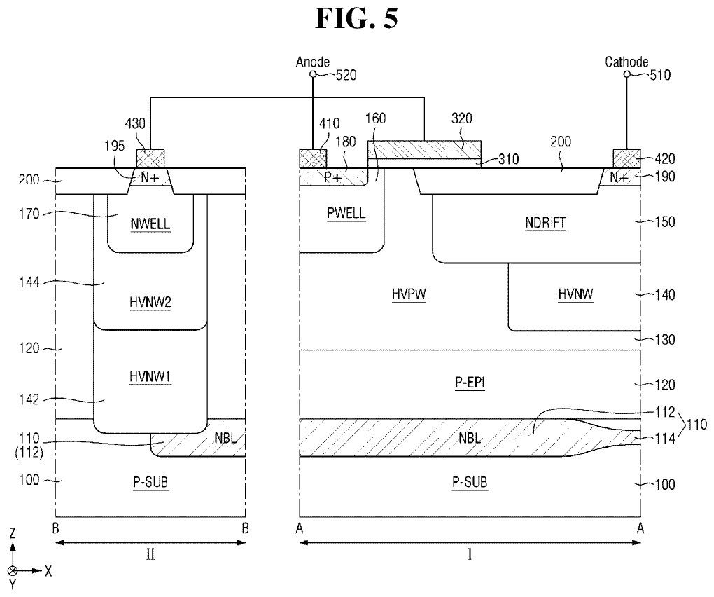

FIG. 5 is cross-sectional view of a semiconductor device according to some embodiments of the present disclosure. For convenience, descriptions of components that that have been described above with reference to FIGS. 1 through 4 may be summarized or omitted.

Referring to FIGS. 1, 2, and 5, in an embodiment, a buried layer 110 includes a base portion 112 and an extension portion 114.

The base portion 112 is formed in the first and second regions I and II. The extension portion 114 extends from the base portion 112 in the first region. The extension portion 114 is formed below the second high-voltage wells 140. At least a portion of the extension portion 114 overlaps the second high-voltage wells 140 in a third direction Z. In some embodiments, at least a portion of the extension portion 114 overlaps the second high-concentration impurity regions 190 in the third direction Z.

The impurity concentration of the extension portion 114 is lower than the impurity concentration of the base portion 112. The extension portion 114 can more effectively prevent the punch-through phenomenon between the buried layer 110 and depletion regions caused by the second high-voltage wells 140. In some embodiments, the impurity concentration of the extension portion 114 decreases with increasing distance from the base portion 112. For example, the extension portion 114 is an impurity region formed by the diffusion of impurity atoms from the base portion 112.

In some embodiments, the thickness of the extension portion 114 decreases with increasing distance from the base portion 112. For example, the top surface of the extension portion 114 becomes lower away from the base portion 112, and the bottom surface of the extension portion 114 becomes higher away from the base portion 112.

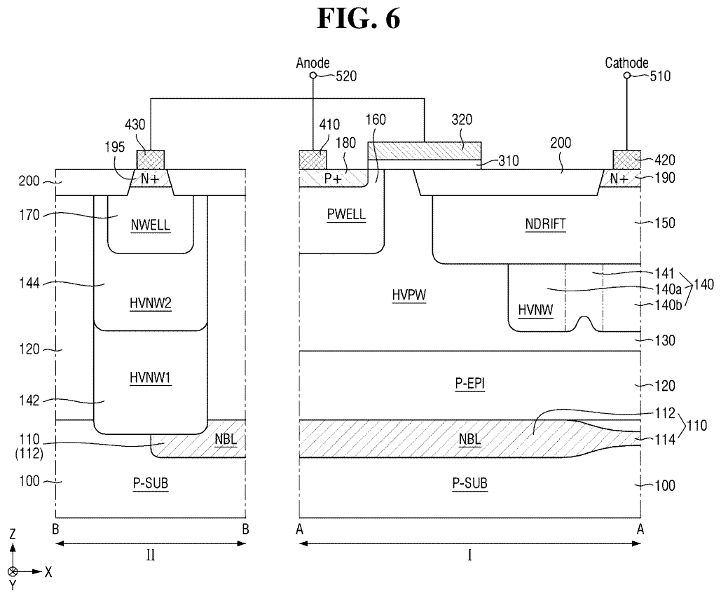

FIG. 6 is a cross-sectional view of a semiconductor device according to some embodiments of the present disclosure. For convenience, descriptions of components that have been described above with reference to FIGS. 1 through 5 may be summarized or omitted.

Referring to FIGS. 1, 2, and 6, in an embodiment, the second high-voltage wells 140 include first portions 140a, second portions 140b, and third portions 141.

The first portions 140a and the second portions 140b are arranged in a direction, such as a first direction X, in which first high-concentration impurity regions 180 and second high-concentration impurity regions 190 are arranged. The third portions 141 are interposed between the first portions 140a and the second portions 140b. For example, the first portions 140a, the third portions 141, and the second portions 140b are sequentially arranged in the first direction X.

In some embodiments, the first portions 140a overlap a device isolation film 200 in a third direction Z. In some embodiments, the second portions 140b overlap the second high-concentration impurity regions 190 in the third direction Z.

The depth at which the third portions 141 are formed is less than the depth at which the first portions 140a and the second portions 140b are formed. For example, the bottom surfaces of the third portions 141 are higher than the bottom surfaces of the first portions 140a and the second portions 140b. In some embodiments, the bottom surfaces of the third portions 141 become higher away from the first portions 140a and the second portions 140b. For example, the third portions 141 are impurity regions formed by the diffusion of impurity atoms from the first portions 140a and the second portions 140b.

In some embodiments, the impurity concentration of the third portions 141 is lower than the impurity concentration of the first portions 140a and the impurity concentration of the second portions 140b. In some embodiments, the impurity concentration of the third portions 141 decreases with increasing distance from the first portions 140a and the second portions 140b, but embodiments of the present disclosure are not necessarily limited thereto. In some embodiments, the impurity concentration of the first portion 140a, the impurity concentration of the second portion 140b, and the impurity concentration of the third portion 141 is substantially the same.

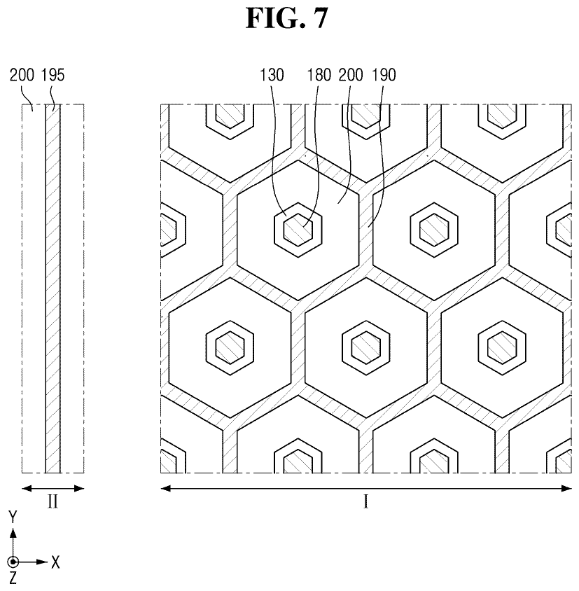

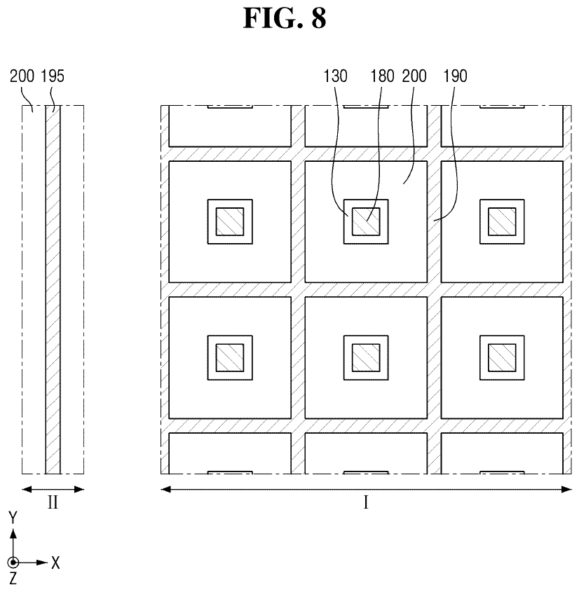

FIG. 7 illustrates a layout of a semiconductor device according to some embodiments of the present disclosure. FIG. 8 illustrates a layout of a semiconductor device according to some embodiments of the present disclosure. For convenience, descriptions of components that have been described above with reference to FIGS. 1 through 6 may be summarized or omitted.

Referring to FIGS. 7 and 8, in some embodiments, second high-concentration impurity regions 190 surround first high-concentration impurity regions 180.

For example, in a plan view, a plurality of first high-concentration impurity regions 180 are arranged as a plurality of isolated areas, and second high-concentration impurity regions 190 surround the first high-concentration impurity regions 180.

In an embodiment, as illustrated in FIG. 7, in a plan view, the first high-concentration impurity regions 180 are arranged in a honeycomb pattern, and the second high-concentration impurity regions 190 have a hexagonal shape that surrounds the first high-concentration impurity regions 180.

In an embodiment, as illustrated in FIG. 8, in a plan view, the first high-concentration impurity regions 180 are arranged in a lattice pattern, and the second high-concentration impurity regions 190 have a rectangular shape that surrounds the first high-concentration impurity regions 180.

As described above, the second high-voltage wells 140 overlap the second high-concentration impurity regions 190 in a third direction Z. Therefore, in a plan view, the second high-voltage wells 140 also surround the first high-concentration impurity regions 180. The second high-voltage wells 140 can enhance the RESURF effect by enlarging depletion regions in both a horizontal direction, such as in an XY plane, and a vertical direction, such as the third direction Z. Consequently, high-voltage power diodes with a further improved breakdown voltage can be provided.

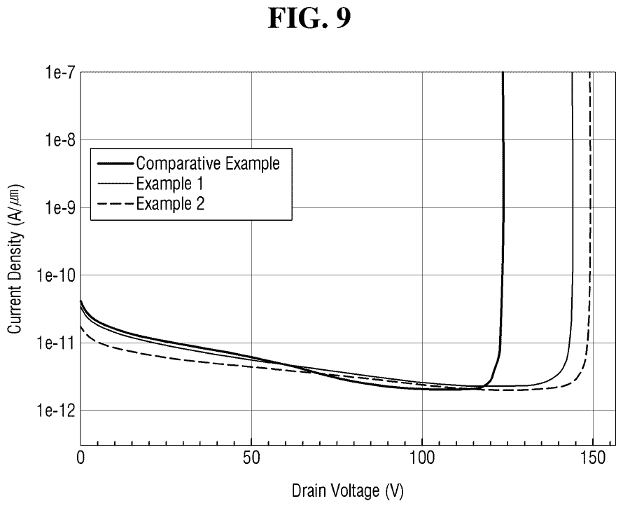

FIG. 9 is a graph of the breakdown voltage of a semiconductor device according to some embodiments of the present disclosure. For example, FIG. 9 is a graph that compares off-state current measurements from Example 1, Comparative Example, and Example 2. Example 2 used a semiconductor device of FIG. 7.

Referring to FIG. 9, a semiconductor device according to Example 2 has an improved breakdown voltage of about 149 V. This confirms that the use of the second high-voltage wells 140 of FIG. 7 can further enhance the breakdown voltage of high-voltage power diodes.

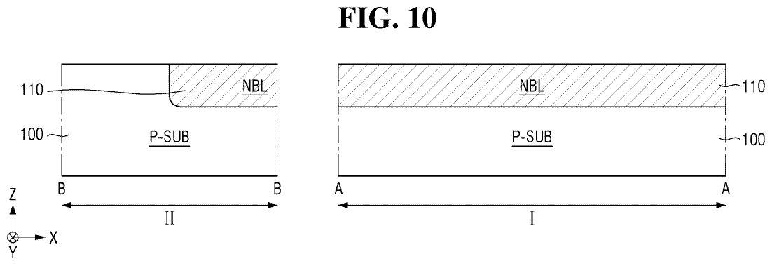

A method of fabricating a semiconductor device according to some embodiments of the present disclosure will hereinafter be described with reference to FIGS. 10 through 20.

FIGS. 10 through 18 are cross-sectional views that illustrate intermediate stages of a method of fabricating a semiconductor device according to some embodiments of the present disclosure. For convenience, descriptions of components that have been described above with reference to FIGS. 1 through 9 may be summarized or omitted.

Referring to FIG. 10, in an embodiment, a buried layer 110 is formed on a substrate 100.

For example, the substrate 100 is as a P-type substrate (“P-SUB”). Thereafter, an ion implantation process that dopes N-type impurities, such as P, is performed on the top surface of the substrate 100. As a result, an N-type buried layer (“NBL”) is formed as the buried layer 110.

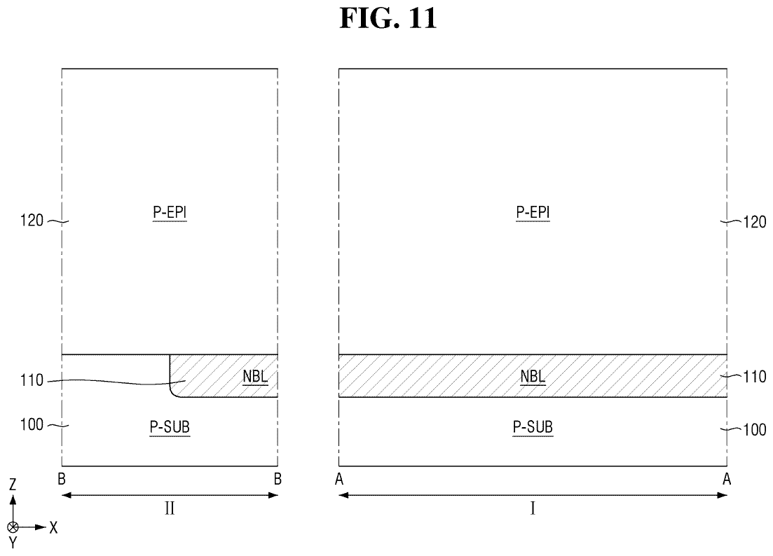

Referring to FIG. 11, in an embodiment, an epitaxial layer 120 is formed on the substrate 100 and the buried layer 110.

The epitaxial layer 120 may be formed by a selective epitaxial growth method or a solid-phase epitaxial growth method, but embodiments of the present disclosure are not necessarily limited thereto. A P-type epitaxial layer (“P-EPI”) is formed as the epitaxial layer 120.

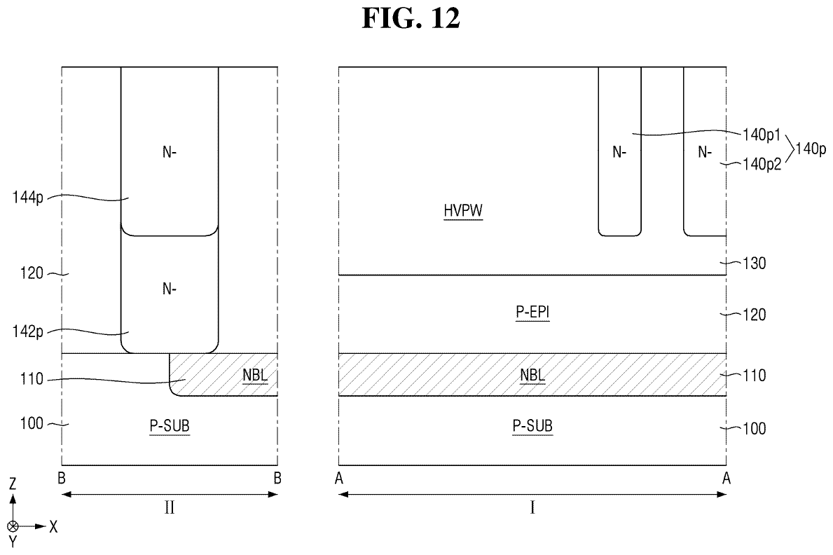

Referring to FIG. 12, in an embodiment, first high-voltage wells 130, preliminary high-voltage wells 140p, a first preliminary isolation well 142p, and a second preliminary isolation well 144p are formed within the epitaxial layer 120.

For example, an ion implantation process is performed that dopes P-type impurities into an upper part of the epitaxial layer 120 in a first region I. As a result, high-voltage P-type wells (“HVPW”) are formed as the first high-volage wells 130.

Furthermore, for example, an ion implantation process is performed that dopes N-type impurities into the epitaxial layer 120 in a second region II. As a result, the first preliminary isolation well 142p is formed on the buried layer 110 in the second region II. Thereafter, an ion implantation process is performed that dopes N-type impurities with a projected range (Rₚ) less than that of the first preliminary isolation well 142p into the epitaxial layer 120 in the first and second regions I and II. As a result, the preliminary high-voltage wells 140p and the second preliminary isolation well 144p with shallower depths than the first preliminary isolation well 142p are formed.

In some embodiments, the preliminary high-voltage wells 140p include first low-concentration impurity regions 140p1 and second low-concentration impurity regions 140p2 that are spaced apart from the first low-concentration impurity regions 140p1. For example, the first low-concentration impurity regions 140p1 and the second low-concentration impurity regions 140p2 are spaced apart from each other in a first direction X. The preliminary high-voltage wells 140p may be formed through a slit-type ion implantation process that dopes N-type impurities into a predetermined pattern using a photoresist, but embodiments of the present disclosure are not necessarily limited thereto.

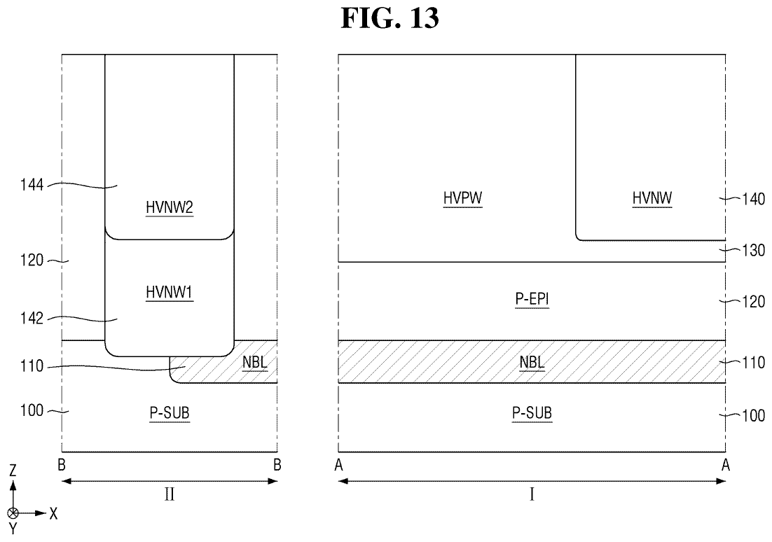

Referring to FIG. 13, in an embodiment, second high-voltage wells 140 and isolation wells 142 and 144 are formed within the epitaxial layer 120.

For example, a heat treatment process, such as an annealing process, is performed on the preliminary high-voltage wells 140p and the first and second preliminary isolation wells 142p and 144p of FIG. 12. As a result, impurity atoms doped in the preliminary high-voltage wells 140p may diffuse, resulting in the formation of second high-voltage wells 140. In addition, impurity atoms doped in the first preliminary and second isolation wells 142p and 144p may diffuse, resulting in the formation of isolation wells 142 and 144 that include the first and second sub-isolation wells 142 and 144. The heat treatment process may be performed immediately after the formation of the preliminary high-voltage wells 140p and the first and second preliminary isolation wells 142p and 144p, but embodiments of the present disclosure are not necessarily limited thereto. One skilled in the art to which the present disclosure pertains will understand that the heat treatment process can also be performed during or after subsequent stages.

Since the second high-voltage wells 140 are formed from the preliminary high-voltage wells 140p that include the first and second low-concentration impurity regions 140p1 and 140p2, the impurity concentration of the second high-voltage wells 140 can be reduced. For example, the impurity concentration of the second high-voltage wells 140 is lower than the impurity concentration of the second sub-isolation well 144.

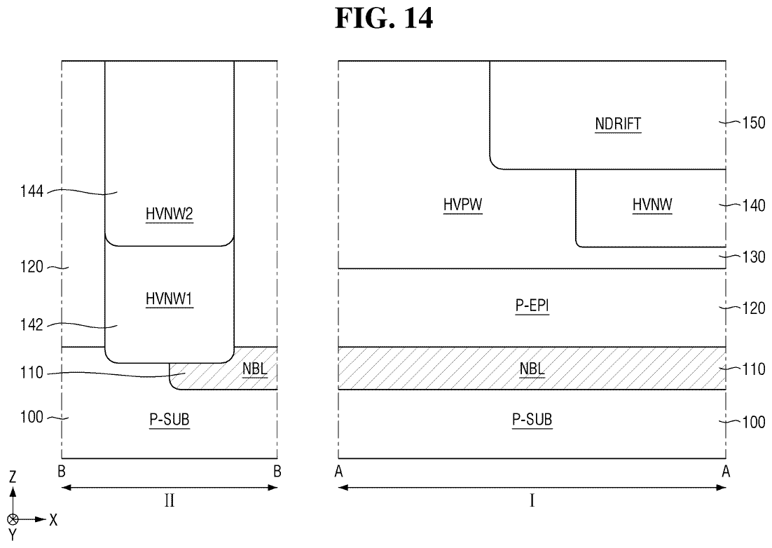

Referring to FIG. 14, in an embodiment, drift regions 150 are formed within the epitaxial layer 120 on the first region I.

For example, an ion implantation process is performed that dopes a low-concentration of N-type impurities into upper parts of the first high-voltage wells 130 on the second high-voltage wells 140. As a result, N-type drift regions (“NDRIFT”) are formed as the drift regions 150.

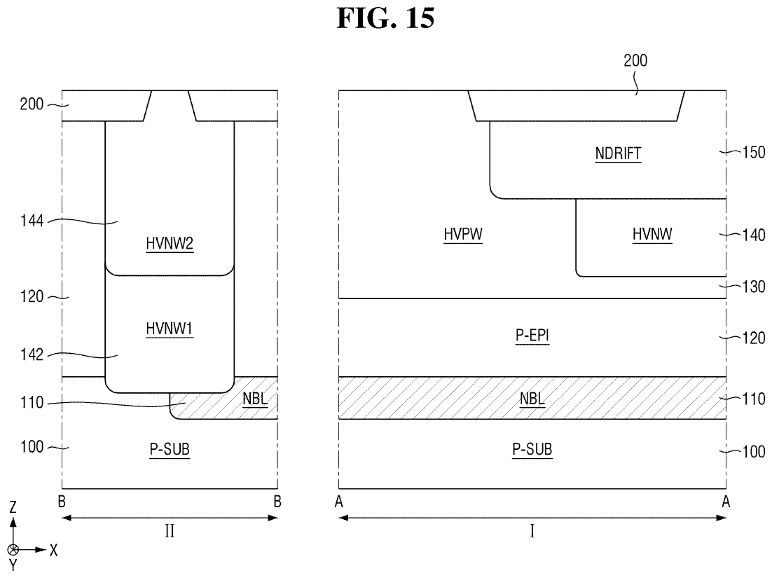

Referring to FIG. 15, in an embodiment, a device isolation film 200 is formed within the epitaxial layer 120.

The device isolation film 200 is formed within the upper part of the epitaxial layer 120. The device isolation film 200 in the first region I is formed on the drift regions 150 and exposes portions of the drift regions 150. In some embodiments, the device isolation film 200 in the second region II is formed on the epitaxial layer 120 and the isolation wells 142 and 144 and exposes part of the isolation wells 142 and 144.

The device isolation film 200 is an oxide layer formed by, for example, an STI or LOCOS process, but embodiments of the present disclosure are not necessarily limited thereto.

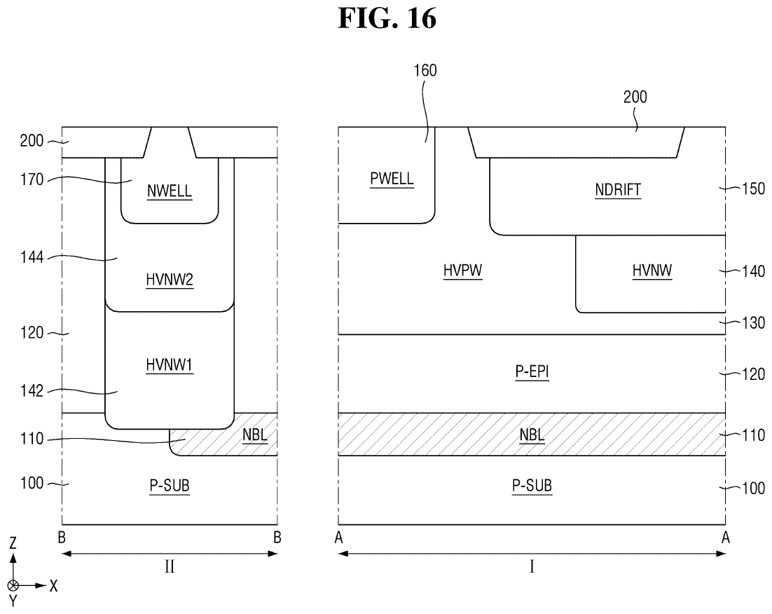

Referring to FIG. 16, in an embodiment, first well regions 160 are formed within the first high-volage wells 130 in the first region I, and a second well region 170 is formed within the second sub-isolation well 144 in the second region II.

For example, an ion implantation process is performed that dopes P-type impurities on upper portions of the first high-voltage wells 130 that are isolated from the drift regions 150 and the device isolation film 200. As a result, P-type wells (“PWELL”) are formed as first well regions 160.

In addition, for example, an ion implantation process is performed that dopes N-type impurities into an upper part of the isolation wells 142 and 144. As a result, an N-type well (“NWELL”) is formed as a second well region 170.

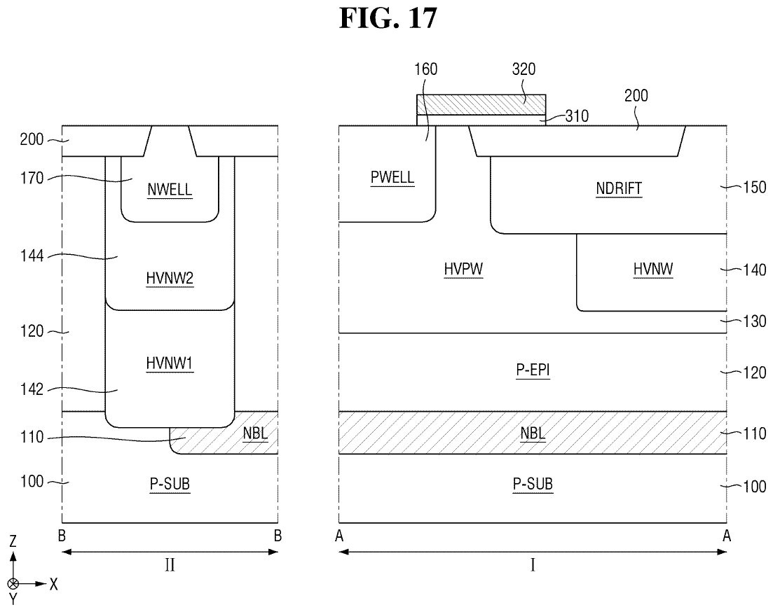

Referring to FIG. 17, in an embodiment, gate dielectric films 310 and gate electrodes 320 are sequentially formed on the epitaxial layer 120 on the first region I.

The gate dielectric films 310 and the gate electrodes 320 are formed over parts of the epitaxial layer 120 and device isolation film 200. For example, the gate dielectric films 310 and the gate electrodes 320 are formed over parts of the first well regions 160, first high-voltage wells 130, and device isolation film 200.

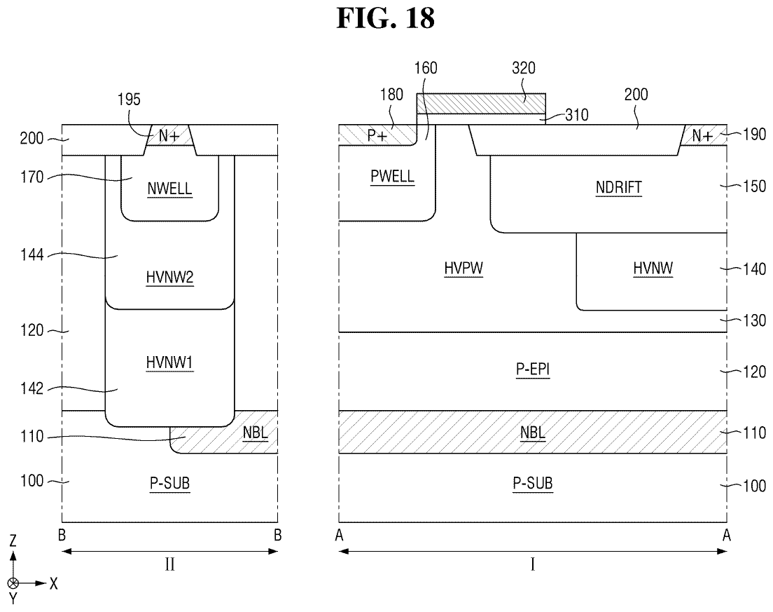

Referring to FIG. 18, in an embodiment, high-concentration impurity regions 180, second high-concentration impurity regions 190, and third high-concentration impurity region 195 are formed on the epitaxial layer 120.

For example, an ion implantation process is performed that dopes high-concentration P-type impurities on the first well regions 160 exposed by the gate dielectric films 310 and gate electrodes 320. As a result, first high-concentration impurity regions 180 are formed.

In addition, for example, an ion implantation process is performed that dopes high-concentration N-type impurities into upper parts of the drift regions 150 exposed by the device isolation film 200 and into an upper part of the second well region 170. As a result, second high-concentration impurity regions 190 and a third high-concentration impurity region 195 are formed.

Thereafter, referring to FIG. 3, in an embodiment, first electrodes 410, second electrodes 420, and third electrodes 430 are formed on the epitaxial layer 120. As a result, the semiconductor device of FIGS. 1 through 3 can be obtained.

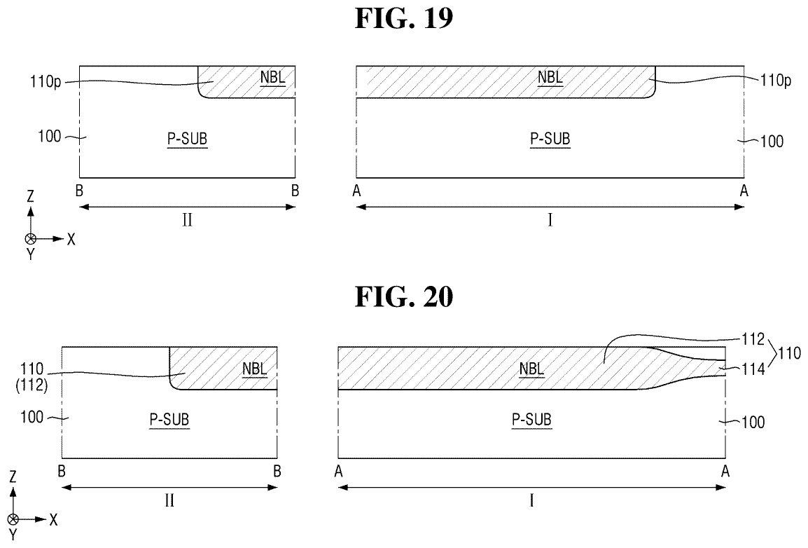

FIGS. 19 and 20 are cross-sectional views that illustrate a method of fabricating a semiconductor device according to some embodiments of the present disclosure. For convenience, descriptions of components that have been described above with reference to FIGS. 1 through 19 may be summarized or omitted.

Referring to FIG. 19, in an embodiment, a preliminary buried layer 110p is formed on a substrate 100.

For example, an ion implantation process is performed that dopes N-type impurities, such as P, into an upper part of the substrate 100. As a result, an N-type buried layer (“NBL”) is formed as the preliminary buried layer 110p.

The preliminary buried layer 110p is formed on an upper portion of a first region I and but not on another upper portion of the first region I. For example, the preliminary buried layer 110p may expose part of the top surface of the substrate 100 on the first region I.

Referring to FIG. 20, in an embodiment, a buried layer 110 that includes a base portion 112 and an extension portion 114 is formed on the substrate 100.

For example, a heat treatment process, such as an annealing process, is performed on the preliminary buried layer 110p of FIG. 19. As a result, impurity atoms doped into the preliminary buried layer 110p may diffuse, resulting in the formation of the base portion 112. In addition, the impurity atoms doped in the preliminary buried layer 110p diffuse into the upper part of the first region I where the preliminary buried layer 110p is not formed, resulting in the formation of the extension portion 114. The heat treatment process may be performed immediately after the formation of the preliminary buried layer 110p, but embodiments of the present disclosure are not necessarily limited thereto. One skilled in the art to which the present disclosure pertains will understand that the heat treatment process may also be performed during or after subsequent stages.

What is claimed is:

1. A semiconductor device, comprising:
a substrate that includes a first region and a second region that surrounds the first region;
an epitaxial layer disposed in the first and second regions, wherein the epitaxial layer has a first conductivity type;
a buried layer disposed below the epitaxial layer, wherein the buried layer has a second conductivity type that differs from the first conductivity type;
a first high-concentration impurity region within the epitaxial layer in the first region, wherein the first high-concentration impurity region overlaps a top surface of the epitaxial layer and has the first conductivity type;
a second high-concentration impurity region within the epitaxial layer in the first region, wherein the second high-concentration impurity region overlaps the top surface of the epitaxial layer and has the second conductivity type;
a device isolation film disposed on the epitaxial layer between the first and second high-concentration impurity regions, wherein the device isolation film is disposed adjacent to the second high-concentration impurity region;
a drift region within the epitaxial layer below the device isolation film and second high-concentration impurity region, wherein the drift region has the second conductivity type;
a high-voltage well within the epitaxial layer below the drift region, wherein the high-voltage well has the second conductivity type;
a third high-concentration impurity region within the epitaxial layer in the second region, wherein the third high-concentration impurity region overlaps the top surface of the epitaxial layer and has the second conductivity type; and
an isolation well within the epitaxial layer in the second region, wherein the isolation well connects the buried layer and the third high-concentration impurity region and has the second conductivity type,
wherein an impurity concentration of the high-voltage well is lower than an impurity concentration of the isolation well.

2. The semiconductor device of claim 1, wherein at least a portion of the high-voltage well overlaps the second high-concentration impurity region in a direction that intersects a top surface of the substrate.

3. The semiconductor device of claim 1, wherein an impurity concentration of the drift region is lower than an impurity concentration of the second high-voltage impurity region.

4. The semiconductor device of claim 1, wherein the impurity concentration of the high-voltage well is lower than an impurity concentration of the second high-voltage impurity region.

5. The semiconductor device of claim 1, wherein a same voltage is applied to the first and third high-concentration impurity regions.

6. The semiconductor device of claim 1, wherein the third high-concentration impurity region surrounds the epitaxial layer in the first region.

7. The semiconductor device of claim 1, further comprising:
a gate electrode disposed on the epitaxial layer between the first and second high-concentration impurity regions, wherein the gate electrode is adjacent to the first high-concentration impurity region.

8. The semiconductor device of claim 7, wherein a same voltage is applied to the first high-concentration impurity region and the gate electrode.

9. The semiconductor device of claim 1, wherein
the buried layer includes a base portion that is located below the first high-concentration impurity region, and an extension portion that extends from the base portion and is located below the high-voltage well, and
an impurity concentration of the extension portion is lower than an impurity concentration of the base portion.

10. The semiconductor device of claim 1, wherein the second high-concentration impurity region surrounds the first high-concentration impurity region.

11. The semiconductor device of claim 1, wherein
the isolation well includes a first sub-isolation well that is connected to the buried layer, and a second sub-isolation well that connects the first sub-isolation well and the third high-concentration impurity region, and
the impurity concentration of the high-voltage well is lower than an impurity concentration of the second sub-isolation well.

12. A semiconductor device, comprising:
a substrate;
an epitaxial layer disposed on the substrate, wherein the epitaxial layer has a first conductivity type;
a buried layer disposed below the epitaxial layer, wherein the buried layer has a second conductivity type that differs from the first conductivity type;
a first high-concentration impurity region within the epitaxial layer, wherein the first high-concentration impurity region overlaps a top surface of the epitaxial layer and has the first conductivity type;
a second high-concentration impurity region within the epitaxial layer, wherein the second high-concentration impurity region overlaps the top surface of the epitaxial layer and has the second conductivity type;
a device isolation film disposed on the epitaxial layer between the first and second high-concentration impurity regions, wherein the device isolation film is adjacent to the second high-concentration impurity region;
a drift region within the epitaxial layer below the device isolation film and second high-concentration impurity region, wherein the drift region has the second conductivity type; and
a high-voltage well within the epitaxial layer below the drift region, wherein the high-voltage well has the second conductivity type,
wherein the buried layer includes a base portion below the first high-concentration impurity region, and an extension portion that extends from the base portion and is below the high-voltage well, and
an impurity concentration of the extension portion is lower than an impurity concentration of the base portion.

13. The semiconductor device of claim 12, wherein a thickness of the extension portion decreases with increasing distance from the base portion.

14. The semiconductor device of claim 12, wherein the impurity concentration of the extension portion decreases with increasing distance from the base portion.

15. The semiconductor device of claim 12, further comprising:
a gate electrode disposed on the epitaxial layer between the first and second high-concentration impurity regions, wherein the gate electrode is adjacent to the first high-concentration impurity region.

16. The semiconductor device of claim 15, wherein a same voltage is applied to the first high-concentration impurity region and the gate electrode.

17. The semiconductor device of claim 12, wherein the second high-concentration impurity region surrounds the first high-concentration impurity region.

18. A semiconductor device, comprising:
a substrate that includes a first region and a second region that surrounds the first region;
a P-type epitaxial layer disposed in the first and second regions;
an N-type buried layer disposed below the P-type epitaxial layer;
a P-type high-concentration impurity region within the P-type epitaxial layer in the first region, wherein the P-type high-concentration impurity region overlaps a top surface of the P-type epitaxial layer;
a first N-type high-concentration impurity region within the P-type epitaxial layer in the first region, wherein the first N-type high-concentration impurity region overlaps the top surface of the P-type epitaxial layer;
a device isolation film disposed on the P-type epitaxial layer between the P-type high-concentration impurity region and the first N-type high-concentration impurity region, wherein the device isolation film is adjacent to the first N-type high-concentration impurity region;
a gate electrode disposed on the P-type epitaxial layer between the P-type high-concentration impurity region and the first N-type high-concentration impurity region, wherein the gate electrode is adjacent to the P-type high-concentration impurity region;
an N-type drift region disposed the P-type epitaxial layer below the device isolation film and first N-type high-concentration impurity region;
an N-type high-voltage well within the P-type epitaxial layer below the N-type drift region;
a second N-type high-concentration impurity region within the P-type epitaxial layer in the second region, wherein the second N-type high-concentration impurity region is between the top surfaces of the P-type epitaxial layer; and
an N-type isolation well disposed within the P-type epitaxial layer in the second region, wherein the N-type isolation well connects the N-type buried layer and the second N-type high-concentration impurity region,
wherein an impurity concentration of the N-type high-voltage well is lower than an impurity concentration of the N-type isolation well,
the N-type buried layer includes a base portion below the P-type high-concentration impurity region, and an extension portion that extends from the base portion and is located below the high-voltage well, and
an impurity concentration of the extension portion is lower than an impurity concentration of the base portion.

19. The semiconductor device of claim 18, wherein a ground voltage is applied to the P-type high-concentration impurity region, the gate electrode, and the second N-type high-concentration impurity region.

20. The semiconductor device of claim 18, wherein the first N-type high-concentration impurity region surrounds the P-type high-concentration impurity region.
